(19) United States
(12) Patent Application Publication
(10) Pub. No.: US 2002/0109189 A1
(43) Pub. Date: Aug. 15, 2002

(54) Method and structure for providing ESD protection for silicon on insulator integrated circuits

(76) Inventors: Shiao-Shien Chen, Chung-Li City (TW); Tien-Hao Tang, Hsin-Chu City (TW)

Correspondence Address: Powell, Goldstein, Frazer & Murphy, LLP, Suite 600, 1001 Pennsylvania Avenue, Washington, DC, 20004, US

(21) Appl. No.: 09/783,869

(22) Filed: Feb. 15, 2001

(51) Int. Cl. H01L 27/01

(52) U.S. Cl. 257/350

(57) ABSTRACT

A method and structure for providing ESD protection for silicon-on-insulator integrated circuits are provided. The ESD protection circuit includes an electrically conductive pad and a conductor segment fabricated over an insulating layer. The conductor segment connects the pad directly to a node. A first diode is fabricated over the insulating layer and connected between the node and a first voltage supply terminal, and the cathode of the first diode is connected to the first voltage supply terminal. A discharge path between the pad and the first voltage supply terminal is constituted through the first diode under the reverse-biased condition. A second diode is fabricated over the insulating layer and connected between the node and a second voltage supply terminal, and the anode of the second diode is connected to the second voltage supply terminal. A discharge path between the node and the second voltage supply terminal is constituted through the second diode under the reverse-biased condition. The node of the ESD protection circuit is coupled to the SOI integrated circuit to be protected. The ESD protection circuit could effectively protect SOI integrated circuits from high voltage related stress, minimize additional process complexities and avoid excessive physical area requirements.

### BACKGROUND OF THE INVENTION

1. Field of the Invention

The present invention relates to electrostatic discharge protection for an integrated circuit, and more specifically, to a method and structure for providing ESD protection for an integrated circuit fabricated in accordance with silicon on insulator technology.

2. Description of the Prior Art

FIG. 1 is a schematic circuit diagram of a conventional SOI integrated circuit electrostatic discharge (ESD) protection device 100 which is coupled between an input pad 101 and a SOI integrated circuit 102. The ESD protection device 100 includes a first n-channel field effect transistor 103 coupled between the input pad 101 and a Vdd voltage supply terminal 106 and a second n-channel field effect transistor 104 coupled between the input pad 101 and a Vss voltage supply terminal 107. The ESD protection device 100 protects the SOI integrated circuit 102 by providing current paths through the p-channel field effect transistor 103 and the n-channel field effect transistor 104 when high positive or negative voltages (relative to the normal operating voltages of the Vdd and Vss voltage supply terminal 106 and 107) applied on the input pad 101.

The p source region of the p-channel field effect transistor 103 is connected to the Vdd voltage supply terminal 106, and the n type source region of the n-channel field effect transistor 104 is connected to the Vss voltage supply terminal 107. Because both of the two MOS field effect transistors 103 and 104 are fabricated in bulk silicon (i.e., substrate), a parasitic PN diode 103a/104a exists between their substrate and drain region. Consequently, if a positive voltage is applied to the input pad 101 with respect to the voltage applied to the Vdd voltage supply terminal 106, an electrically conductive path is formed between the Vdd voltage supply terminal 106 and the input pad 101 through the parasitic PN diode 103a between the drain region and substrate of the p channel field effect transistor 103. This electrically conductive path allows a high positive current to flow between the Vdd voltage supply terminal 106 and the input pad 101 without damaging the SOI integrated circuit 102.

Additionally, if a negative voltage is applied to the input pad 101 with respect to the Vss voltage supply terminal 107, current will flow from the input pad 101 to the Vss voltage supply terminal 107 through the PN parasitic diode 104a between the substrate and the drain region of the n-channel field effect transistor 104.

Thus, parasitic PN junctions formed in devices fabricated in bulk silicon are useful in providing ESD protection at the input terminals of the integrated circuits. However, in utilizing a pair of field effect transistors between the Vdd voltage supply terminal and the Vss voltage supply terminal to serve as the ESD protection device of the SOI integrated circuit 102, as shown in FIG. 1, the process complexity for the ESD protection device is increased except for occupying more area. Additionally, since the ESD protection device is fabricated in an insulating layer, such as a silicon dioxide layer, which has a low thermal conductivity, the heat dissipation region is surrounded by the insulating layer. The more the area occupied by the ESD protection device, the lower the heat dissipation efficiency. And, the lower efficient heat dissipation also reduces the ESD capability.

Accordingly, there is a need to provide a SOI ESD protection device complied with the requirement of minimum occupied area, not increasing process complexity and provide good ESD capability.

### SUMMARY OF THE INVENTION

It is one object of the present invention to provide a SOI ESD protection circuit using two zener diodes serving as the ESD protection devices between a Vdd voltage supply terminal and a Vss voltage supply terminal. The ESD protection circuit could effectively protects SOI integrated circuits from high voltage related stress, minimizes additional process complexities and avoids excessive physical area requirements.

It is another object of the present invention to provide a SOI ESD protection circuit using two zener diodes serving as the ESD protection elements between a Vdd voltage supply terminal and a Vss voltage supply terminal. Each of the two zener diodes is constituted of a heavily doped diffusion region with a first conductive type, a well with a second conductive type being opposite to the first conductive type and a heavily doped diffusion region with the second conductive type formed in the well, all of which are fabricated over an insulating layer. Therefore, the process for fabricating the ESD protection devices is compatible with the SOI technology.

It is a further object of the present invention to provide a method for providing ESD protection for silicon on insulator integrated circuits, in which the current is conducted from a pad to a Vdd voltage supply terminal through a first reverse-biased SOI zener diode when a voltage applied to a pad is negative with respect to a voltage applied to the Vdd voltage supply terminal, and the current is conducted from a pad to a Vss voltage supply terminal through a second reverse-biased SOI zener diode when a voltage applied to a pad is positive with respect to a voltage applied to the Vss voltage supply terminal.

Accordingly, the present invention provides an SOI ESD protection circuit with the above-mentioned advantages. An ESD protection circuit in accordance with the present invention includes an electrically conductive pad and a conductor segment fabricated over an insulating layer. The conductor segment connects the pad directly to a node. A first diode is fabricated over the insulating layer and connected between the node and a first voltage supply terminal, and the cathode of the first diode is connected to the first voltage supply terminal, such that the first diode is reverse-biased by a negative voltage applied to the pad with respect to the voltage applied to the first voltage supply terminal. A second diode is fabricated over the insulating layer and connected between the pad and a second voltage supply terminal, and the anode of the second diode is connected to the second voltage supply terminal, such that the second diode is reverse-biased by a positive voltage applied to the pad with respect to the voltage applied to the second voltage supply terminal.

### BRIEF DESCRIPTION OF THE DRAWINGS

The present invention can be best understood through the following description and accompanying drawings wherein:

FIG. 1 is a schematic diagram of a conventional SOI ESD protection circuit;

FIG. 2 is a schematic diagram of a SOI ESD protection circuit in accordance with the present invention;

FIG. 3A is a schematic top view of the SOI ESD protection circuit layout of FIG. 2; and

FIG. 3B is a schematic top view of the SOI ESD protection circuit layout of a variation of FIG. 2.

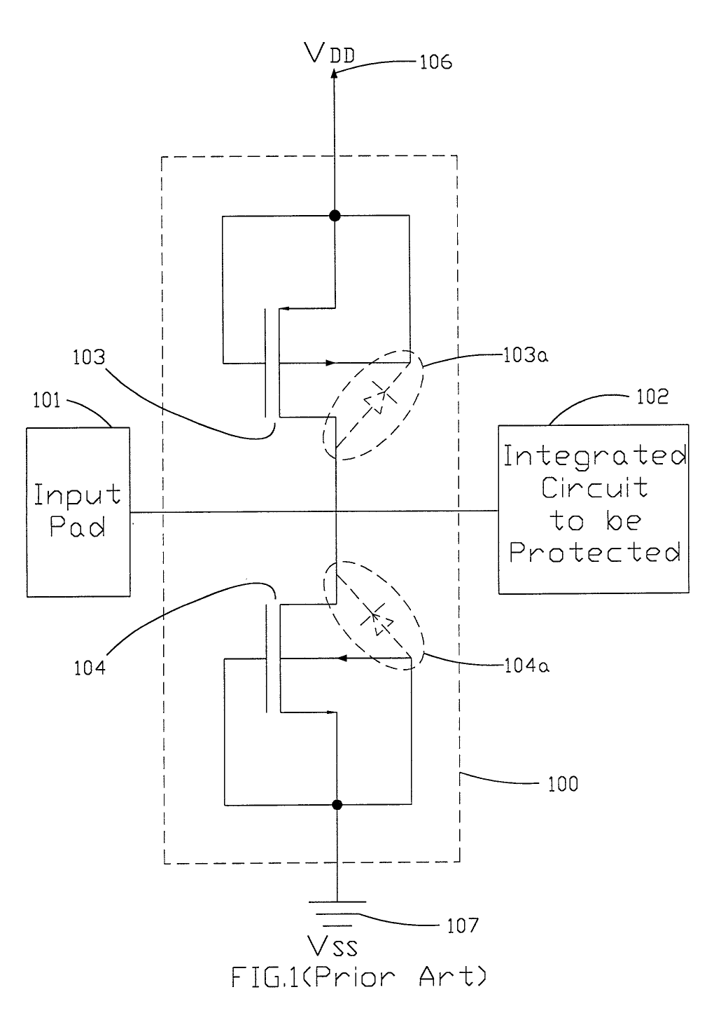

### DESCRIPTION OF THE PREFERRED EMBODIMENT

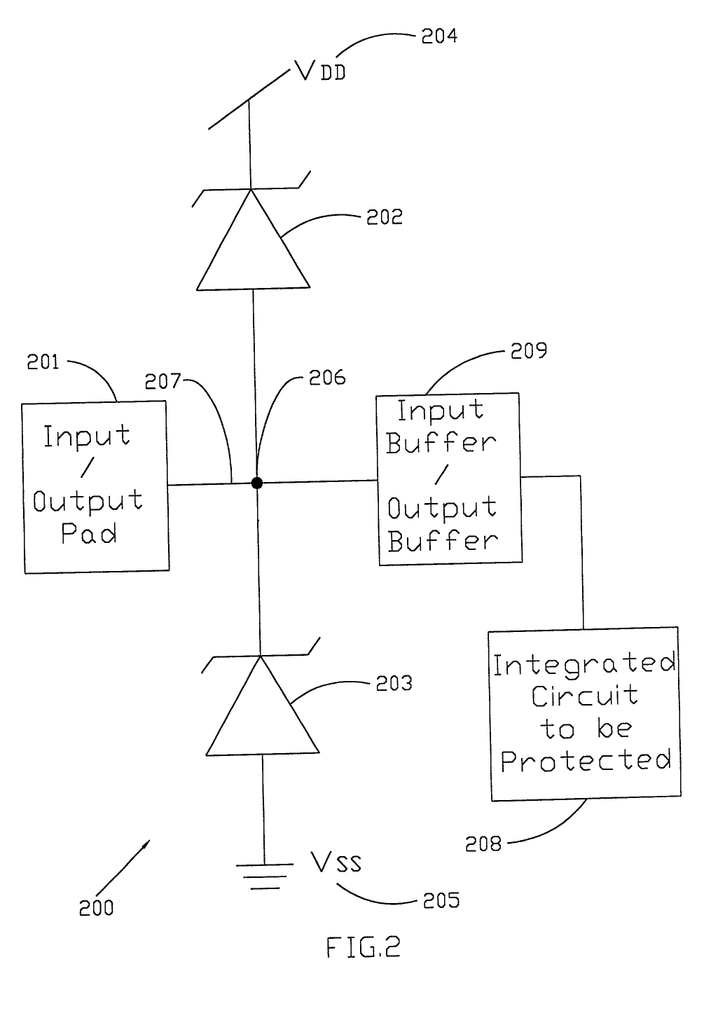

FIG. 2 illustrates one embodiment of a SOI ESD protection circuit 200 in accordance with the present invention including an electrically conductive pad 201, a first zener diode 202, a second zener diode 203, a Vdd voltage supply terminal 204 and a Vss voltage supply terminal 205. The first zener diode 202 and the second zener diode 203 are fabricated over an insulating layer in accordance with SOI technology (i.e., SOI devices), and the insulating layer may be fabricated on a substrate. Although the Vdd voltage supply terminal 204 and Vss voltage supply terminal 205 are held at different voltages in different circuits, in this embodiment Vdd voltage supply terminal 204 is held at 5 volts and Vss voltage supply terminal 205 is grounded during normal operation of the ESD protection circuit 200.

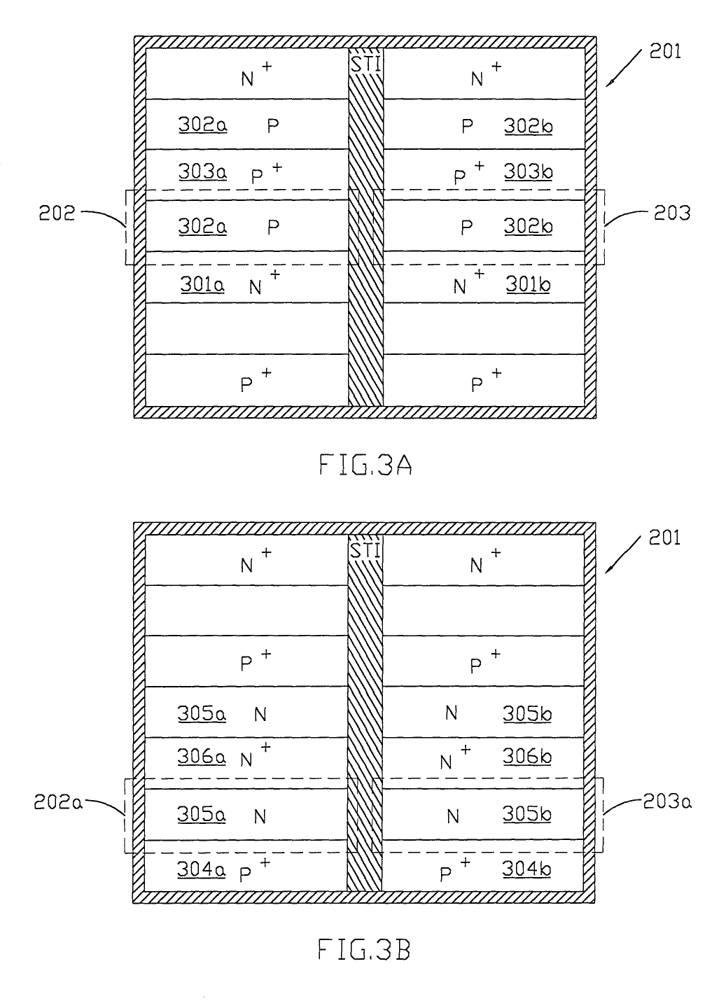

As shown in FIG. 3A, which is a schematic top view of the ESD protection circuit layout of FIG. 2, the first zener diode 202 and the second zener diode 203 are fabricated under the pad 201 which being not fabricated over the insulating layer. While the pad 201 could also be fabricated over the insulating layer together with the first zener diode 202 and the second zener diode 203.

Referring to FIG. 2, the pad 201 is connected directly to a node 206 through a conductor segment 207 fabricated over the insulating layer when the pad 201 is fabricated over the insulating layer, which in turn is coupled to the Vdd voltage supply terminal 204 through the first zener diode 202. Note that the cathode of the first zener diode 202 is connected to the Vdd voltage supply terminal 204. The node 206 is coupled to the Vss voltage supply terminal 203 through the second zener diode 203, wherein the anode of the second zener diode 203 is connected to the Vss voltage supply terminal 205. The node 206 is also coupled to a SOI integrated circuit 208 to be protected. The node 206 could be coupled to the SOI integrated circuit 208 through an input/output buffer 209.

When the ESD event involves the application of a negative voltage to the pad 201 relative to the Vdd voltage supply terminal 204, the first zener diode 202 is reverve-biased and turned on. As a result, the associated ESD current is discharged to the Vdd voltage supply terminal 204 through the first zener diode 202.

Similarly, when the ESD event involves the application of a positive voltage to the pad 201 relative to the Vss voltage supply terminal 205, the second zener diode 203 is reverse-biased and turned on. The ESD current is discharged to the Vss voltage supply terminal 205 through the second zener diode 203.

FIG. 3A is a schematic top view of the SOI ESD protection circuit 200 of FIG. 2. Both of the first zener diode 202 and the second zener diode 203 are fabricated under the pad window 201. And, each of the two zener diodes is constituted of a heavily doped N+ diffusion region, a P diffusion region and a heavily doped P+ diffusion region. The P diffusion region is formed between the heavily doped N+ diffusion region and the heavily doped P+ diffusion region. The dopant concentration of the P diffusion region is adjusted depending on the breakdown voltage of the zener diode. All of these doping regions could be formed by way of the well-known ion implantation method. In more detail, the first zener diode 202 is formed of the N+ diffusion region 301a, the P diffusion region 302a and the P+ diffusion region 303a. The second zener diode 203 is formed of the N+ diffusion region 301b, the P diffusion region 302b and the P+ diffusion region 303b.

In an alternative embodiment, both of the first zener diode 202a and the second zener diode 203a are constituted of a heavily doped P+ diffusion region, an N diffusion region and a heavily doped N+ diffusion region. The N diffusion region is formed between the heavily doped N+ diffusion region and the heavily doped P+ diffusion region. The dopant concentration of the N diffusion region is adjusted depending on the breakdown voltage of the zener diode. All of these doping regions could be formed by way of the well-known ion implantation method. As shown in FIG. 3B, the first zener diode 202a is formed of a P+ diffusion region 304a, an N diffusion region 305a and an N+ diffusion region 306a. The second zener diode 203a is formed of a P+ diffusion region 304b, an N diffusion region 305b and an N+ diffusion region 306b.

Although in the above embodiments, two zener diodes are used as ESD protection elements between the Vdd voltage supply terminal and the Vss voltage supply terminal. The present invention is not limited to only use zener diodes serving as the ESD protection elements. Any diode with PN junction providing the property that under the reverse-biased condition, its junction breakdown is easily happened so as to generate a large quantity of the electron-hole pair, is suitable for used as the ESD protection elements of the present invention.

In view of the forgoing, the SOI ESD protection circuit is directly connected to the SOI integrated circuit to be protected. This advantageously eliminates any input resistor from the signal path between the pad and the protected integrated circuit. As a result, RC delay along this path is greatly reduced. Moreover, because the elements of the SOI ESD protection circuit are fabricated over the insulating layer in accordance with SOI techniques, the complexity of the process required to fabricate the ESD protection circuits is not increased. And also, because of the relatively small layout area associated with the SOI devices, the physical layout requirement of the ESD protection circuit is not excessive.

The preferred embodiments are only used to illustrate the present invention, not intended to limit the scope thereof. Many modifications of the preferred embodiments can be made without departing from the spirit of the present invention.

What is claimed is:

1. An electrostatic discharge (ESD) protection circuit for protecting a silicon-on-insulator (SOI) integrated circuit over an insulating layer, said ESD protection circuit comprising:
an electrically conductive pad fabricated over said insulating layer;
a conductor segment fabricated over said insulating layer, said conductor segment connecting said pad directly to a node coupled to a portion of said SOI integrated circuit;
a first diode fabricated over said insulating layer and connected between said node and a first voltage supply terminal, the cathode of said first diode being connected to said first voltage supply terminal; and
a second diode fabricating over said insulating layer and connected between said node and a second voltage supply terminal, the anode of said second diode being connected to said second voltage supply terminal;
wherein said pad conducts current to said first voltage supply terminal through said first diode in reverse-biased mode when a voltage applied to said pad is negative with respect to a voltage applied to said first voltage supply terminal, and said pad conducts current to said second voltage supply terminal through said second diode in reverse-biased mode when a voltage applied to said pad is positive with respect to a voltage applied to said second voltage supply terminal.

2. The ESD protection circuit of claim 1, wherein said first diode is formed of a first zener diode.

3. The ESD protection circuit of claim 2, wherein said first zener diode is constituted of a first heavily doped diffusion region with a first conductive type, a first diffusion region with a second conductive type being opposite to said first conductive type and a first heavily doped diffusion region with said second conductive type, said first diffusion region with said second conductive type being formed between said first heavily doped diffusion region with said first conductive type and said first heavily doped diffusion region with said second conductive type, and the dopant concentration of said first diffusion region with said second conductive type being adjusted depending on the breakdown voltage of said first zener diode.

4. The ESD protection circuit of claim 3, wherein said first conductive type is either of N type and P type.

5. The ESD protection circuit of claim 1, wherein said second diode is formed of a second zener diode.

6. The ESD protection circuit of claim 5, wherein said second zener diode is constituted of a second heavily doped diffusion region with a first conductive type, a second diffusion region with a second conductive type and a second heavily doped diffusion region with said second conductive type, said second diffusion region with said second conductive type being formed between said second heavily doped diffusion region with said first conductive type and said second heavily doped diffusion region with said second conductive type, and the dopant concentration of said second zener diode being adjusted depending on the breakdown voltage of said second zener diode.

7. The ESD protection circuit of claim 6, wherein said first conductive type is either of N type and P type.

8. The ESD protection circuit of claim 1, wherein said node is connected directly to an input buffer of said SOI integrated circuit.

9. The ESD protection circuit of claim 1, wherein said node is connected to an output buffer of said SOI integrated circuit.

10. A method for providing electrostatic discharge (ESD) protection for a silicon-on-insulator (SOI) integrated circuit, said method comprising the steps of:
coupling an electrically conductive pad of said SOI integrated circuit directly to a portion of said SOI integrated circuit;
conducting current from said pad to a first voltage supply terminal through a reverse-biased first SOI diode when a voltage applied to said pad is negative with respect to a voltage applied said first voltage supply terminal; and
conducting current from said pad to a second voltage supply terminal through a reverse-biased second SOI diode when a voltage applied to said pad is positive with respect to a voltage applied said second voltage terminal.

11. An electrostatic discharge (ESD) protection circuit for protecting a silicon-on-insulator (SOI) integrated circuit, said ESD protection circuit comprising:
an electrically conductive pad;
a conductor segment connecting said pad directly to a node, wherein said node is connected to a portion of said SOI integrated circuit;
a first SOI diode connected between said node and a first voltage supply terminal, wherein the cathode of said first SOI diode is connected to said first voltage supply terminal, and is reverse-biased by a voltage applied to said pad which is negative with respect to a voltage applied to said first voltage supply terminal; and
a second SOI diode connected between said node and a second voltage supply terminal, wherein the anode of said second SOI diode is connected to said second voltage supply terminal and is reverse-biased by a voltage applied to said pad which is positive with respect to a voltage applied to said second voltage supply terminal.

12. The ESD protection circuit of claim 11, wherein said first SOI diode is formed of a first zener diode.

13. The ESD protection circuit of claim 12, wherein said first zener diode is constituted of a first heavily doped diffusion region with a first conductive type, a first diffusion region with a second conductive type being opposite to said first conductive type and a first heavily doped diffusion region with said second conductive type, said first diffusion region with said second conductive type being formed between said first heavily doped diffusion region with said first conductive type and said first heavily doped diffusion region with said second conductive type, and the dopant concentration of said first diffusion region with said second conductive type being adjusted depending on the breakdown voltage of said first zener diode.

14. The ESD protection circuit of claim 13, wherein said first conductive type is either of N type and P type.

15. The ESD protection circuit of claim 11, wherein said second SOI diode is formed of a second zener diode.

16. The ESD protection circuit of claim 15, wherein said second zener diode is constituted of a second heavily doped diffusion region with a first conductive type, a second diffusion region with a second conductive type being opposite to said first conductive type and a second heavily doped diffusion region with said second conductive type, said second diffusion region with said second conductive type being formed between said second heavily doped diffusion region with a first conductive type and said second heavily doped diffusion region with said second conductive type, and the dopant concentration of said second diffusion region being adjusted depending on the breakdown voltage of said second zener diode.

17. The ESD protection circuit of claim 16, wherein said first conductive type is either of N type and P type.

18. The ESD protection circuit of claim 11, wherein said node is connected directly to an input buffer of said SOI integrated circuit.

19. The ESD protection circuit of claim 11, wherein said node is connected to an output buffer of said SOI integrated circuit.
